(19) United States
(12) Patent Application Publication
(10) Pub. No.: US 2018/0138115 A1
(43) Pub. Date: May 17, 2018

(54) SEMICONDUCTOR PACKAGE STRUCTURE AND METHOD FOR MANUFACTURING THE SAME

(71) Applicant: Advanced Semiconductor Engineering, Inc., Kaohsiung (TW)

(72) Inventor: Wen-Long LU, Kaohsiung (TW)

(73) Assignee: Advanced Semiconductor Engineering, Inc.

(21) Appl. No.: 15/349,957

(22) Filed: Nov. 11, 2016

(51) Int. Cl. H01L 23/498; H01L 23/00; H01L 23/31; H01L 21/48; H01L 21/56; H01L 21/66

(52) U.S. Cl. CPC H01L 23/49838; H01L 24/16; H01L 23/49827; H01L 23/3185; H01L 23/3135; H01L 2924/37001; H01L 21/486; H01L 21/563; H01L 21/565; H01L 22/14; H01L 2224/16227; H01L 21/4853

(57) ABSTRACT

A semiconductor package structure includes a dielectric structure defining a plurality of through holes, wherein each of the through holes includes a first portion defined by a first sidewall portion and a second portion defined by a second sidewall portion substantially coplanar with the first sidewall portion. The semiconductor package structure further includes a redistribution layer structure disposed on a first surface of the dielectric structure, including a plurality of conductive pads and a plurality of first conductive traces, wherein each of the conductive pads is disposed in a respective through hole, and a sidewall of the conductive pad contacts the first sidewall portion of the through hole, a semiconductor die electrically connected to the redistribution layer structure, and a plurality of conductive structures each disposed on a respective one of the conductive pads and disposed in the second portion of the through hole, wherein a sidewall of the conductive structure and the second sidewall portion of the through hole define a gap.

### BACKGROUND

### 1. Field of the Disclosure

The present disclosure relates to a semiconductor package structure and a semiconductor process, and more particularly to a semiconductor package structure having thin conductive pads and a method for manufacturing the same.

### 2. Description of the Related Art

Some semiconductor package structures include a plurality of ball pads formed from a copper foil. However, in an initial stage of a manufacturing process, the copper foil may easily wrinkle due to slight structural warpage. Such wrinkling can make it difficult to form the ball pads, or can result in poor quality ball pads. Therefore, such semiconductor package structures may not be acceptable for commercial use. In addition, since the ball pads are formed from the copper foil, the thickness of the ball pads cannot be easily reduced.

### SUMMARY

In some embodiments, according to one aspect, a semiconductor package structure includes a dielectric structure, a redistribution layer structure, a semiconductor die and a plurality of conductive structures. The dielectric structure defines a plurality of through holes. Each of the through holes includes a first portion defined by a first sidewall portion and a second portion defined by a second sidewall portion substantially coplanar with the first sidewall portion. The redistribution layer structure is disposed on a first surface of the dielectric structure, and includes a plurality of conductive pads and a plurality of first conductive traces. Each of the conductive pads is disposed in a respective through hole, and a sidewall of the conductive pad contacts the first sidewall portion of the through hole. The semiconductor die is electrically connected to the redistribution layer structure. The conductive structures are each disposed on a respective one of the conductive pads and disposed in the second portion of the through hole. A sidewall of the conductive structure and the second sidewall portion of the through hole define a gap.

In some embodiments, according to another aspect, a semiconductor package structure includes a dielectric structure, a redistribution layer structure, a semiconductor die and a plurality of conductive structures. The dielectric structure defines a plurality of through holes. The redistribution layer structure is disposed on at least a portion of the dielectric structure, and includes a plurality of conductive pads and a plurality of first conductive traces. Each of the conductive pads is disposed in a respective through hole. The semiconductor die is electrically connected to the redistribution layer structure. The conductive structures are each disposed on a respective one of the conductive pads and in a respective one of the through holes. A portion of each of the conductive structures protrudes beyond the dielectric structure, and a volume of the entire conductive structure is substantially equal to a volume defined by a surface of the conductive pad, the through hole, and a plane parallel to the surface of the conductive pad and coplanar with a surface of the dielectric structure.

In some embodiments, according to another aspect, a method for manufacturing a semiconductor package structure includes: (a) forming a dielectric structure on a carrier, wherein the dielectric structure defines a plurality of through holes; (b) forming a plurality of conductive material deposits, wherein each of the conductive material deposits is disposed in a respective one of the through holes, wherein a thickness of the conductive material deposits is less than a thickness of the dielectric structure; (c) forming a redistribution layer structure on the dielectric structure thus covering at least one surface of the conductive material deposits; (d) electrically connecting a semiconductor die to the redistribution layer structure; (e) removing the carrier to expose the conductive material deposits; and (f) heating the conductive material deposits to form a plurality of conductive structures to protrude beyond the dielectric structure.

### BRIEF DESCRIPTION OF THE DRAWINGS

FIG. 1 illustrates a cross-sectional view of a semiconductor package structure according to some embodiments of the present disclosure.

FIG. 2 illustrates a cross-sectional view of a semiconductor package structure according to some embodiments of the present disclosure.

FIG. 3 illustrates a cross-sectional view of a semiconductor package structure according to some embodiments of the present disclosure.

FIG. 4 illustrates a cross-sectional view of a semiconductor package structure according to some embodiments of the present disclosure.

FIG. 5 illustrates a cross-sectional view of a semiconductor package structure according to some embodiments of the present disclosure.

FIG. 6 illustrates a cross-sectional view of a semiconductor package structure according to some embodiments of the present disclosure.

FIG. 7 illustrates a cross-sectional view of a semiconductor package structure according to some embodiments of the present disclosure.

FIG. 8, FIG. 9, FIG. 10, FIG. 11, FIG. 12, FIG. 13, FIG. 14, FIG. 15, FIG. 16, FIG. 17, FIG. 18, FIG. 19, FIG. 20 and FIG. 21 illustrate a method for manufacturing a semiconductor package structure according to some embodiments of the present disclosure.

FIG. 22 illustrates an enlarged view of an area “A” depicted in FIG. 1 according to the embodiments depicted in FIG. 1.

FIG. 23 illustrates a schematic view of a depiction of a cross section of a conductive structure, according to some embodiments of the present disclosure.

### DETAILED DESCRIPTION

The present disclosure provides an improved semiconductor package structure that includes a plurality of thin conductive pads, and improved techniques for manufacturing the semiconductor package structure. The semiconductor package structure and techniques described in the present disclosure are suitable for high resolution trace fabrication.

A manufacturing process of making a semiconductor package structure may begin with forming a dielectric structure and conductive circuit layer on a copper foil attached on a carrier, followed by bonding a plurality of dice to the conductive circuit layer, and then forming a molding material on the surface of the dielectric structure to encapsulate the dice. After the carrier is removed, the copper foil can be etched to produce a plurality of ball pads. However, during the manufacturing process, the copper foil may easily wrinkle due to slight structural warpage. Such wrinkling can make it difficult to form the ball pads, especially when the wrinkling occurs at an alignment mark. Additionally, before the etching process, a photoresist layer can be formed on the copper foil, and then, the copper foil can be patterned by lithography. However, the roughness of the surface of the copper foil can affect a resolution of the lithography. As a result, for example, a bottom portion of the photoresist layer may be removed in excess of a desired amount by the lithography. Thus, a width of a bottom portion of the photoresist layer may be less than a width of a top portion of the photoresist layer. During the etching process, excess copper is etched away, and because of the above-mentioned problems with the photoresist layer, the width of the remained ball pads or trace may be less than a desired size. In addition, warpage of a panel can occur after a step of removing the carrier before a solder ball mounting process, which can make it difficult to perform the solder ball mounting process. For example, a 300 mm (millimeter)×300 mm panel may exhibit a warpage of about 3.5 cm. It can be difficult to use such a panel to perform the ball mounting process.

Further, the conductive circuit layer (including traces and bump pads) can be formed on a dielectric layer of the dielectric structure by electroless plating. However, in general the minimum uniformity of electroless metal on a nonmetal surface (e.g., the dielectric layer) is greater than 10% due to a metallization particle distribution phenomenon. Thus, it is difficult to manufacture the conductive circuit layer such that it has a line width/line space (L/S) of less than 5 μm (micrometer)/5 μm. Furthermore, a minimum thickness of the dielectric structure (e.g., an organic substrate) is greater than 0.2 mm due to process limitations (e.g., lithography resolution and stripping) and structural limitations (e.g., the thickness of a dielectric layer of the dielectric structure). Thus, a total thickness of the semiconductor package structure cannot be easily reduced. In addition, an electrical test of the semiconductor package structure can be performed on the final product (e.g., the complete semiconductor package structure), that is, the electrical test can be performed after a singulation process, rather than during the manufacturing process. Therefore, any failure of the conductive circuit layer (including the traces and the bump pads) cannot be found prior to completion of the manufacturing process, which results in a low yield rate and high manufacturing cost.

The present disclosure addresses at least the above concerns and provides an improved semiconductor package structure and improved techniques for manufacturing the semiconductor package structure. In one or more embodiments of the present disclosure, even if the copper foil wrinkles, the wrinkling will not prevent manufacture of a precise and finely patterned conductive circuit layer (including the traces and the bump pads). The traces and the bump pads are formed concurrently by high resolution techniques. Thus, the conductive circuit layer can be produced with a line width/line space (L/S) of about 2 μm/about 2 μm, and the thicknesses of the traces and the bump pads can be made very thin. Further, even if warpage occurs after an assembly and de-carrier process, the solder balls can still be formed at predetermined positions. In addition, electrical testing can be performed before a die mounting process. Therefore, failures of the conductive circuit layer (including the traces and the bump pads) can be found immediately, which can raise the yield rate and lower the manufacturing cost.

FIG. 1 illustrates a cross-sectional view of a semiconductor package structure 1 according to some embodiments of the present disclosure. The semiconductor package structure 1 includes a dielectric structure 2, a redistribution layer (RDL) structure 3, an insulation structure 6, a conductive circuit layer 7, a semiconductor die 4, an encapsulant 12 and a plurality of conductive structures 5.

The dielectric structure 2 may be, for example, a passivation layer or a solder mask layer. In some embodiments, the dielectric structure 2 may include, or be formed from, a cured photoimageable dielectric (PID) material such as epoxy or polyimide (PI) including photoinitiators. The dielectric structure 2 has a first surface 21 and a second surface 22 opposite to the first surface 21, and defines a plurality of through holes 23. Each of the through holes 23 extends through the dielectric structure 2, and includes a first sidewall portion 231 that defines a first portion of the through hole 23 and a second sidewall portion 232 that defines a second portion of the through hole 23. The first sidewall portion 231 contacts conductive pads 32 of the redistribution layer structure 3, and the conductive structure 5 is disposed in the second portion of the through hole 23. The second sidewall portion 232 and the first sidewall portion 231 are substantially coplanar with each other and are formed concurrently. In some embodiments, each of the through holes 23 has an approximately consistent diameter. The width W1 of the first portion of the through hole 23 is substantially equal to the width W2 of the second portion of the through hole 23.

The redistribution layer structure 3 is disposed on at least a portion of the first surface 21 of the dielectric structure 2, and includes the plurality of conductive pads 32 and a plurality of first conductive traces 34. The redistribution layer structure 3 may include a plurality of metal layers. As shown in FIG. 1, the redistribution layer structure 3 includes a first metal layer 331 and a second metal layer 332. The material of the first metal layer 331 may include titanium and/or copper, and a thickness of the first metal layer 331 may be in a range of about 0.2 μm to about 0.5 μm. The material of the second metal layer 332 may include copper, and the thickness of the second metal layer 332 may be in a range of about 2 μm to about 5 μm. The first metal layer 331 may be a seed layer which is formed by sputtering and the second metal layer 332 may be formed by pattern plating, and thus, their respective thicknesses can be very thin. It is noted that the first metal layer 331 including titanium is capable of acting as a barrier layer which can prevent the conductive structure 5 (e.g., solder material) from diffusing into the second metal layer 332 and forming an intermetallic compound.

In the embodiments depicted in FIG. 1, each of the conductive pads 32 is disposed in a respective through hole 23, and a sidewall 321 of the conductive pad 32 contacts the first sidewall portion 231 of the through hole 23. That is, portions of the first metal layer 331 and the second metal layer 332 that are disposed in the first portion of the through hole 23 constitute the conductive pad 32 on which the conductive structure 5 may be attached. The conductive pad 32 is sometimes referred to herein as the “ball pad”. The thickness of the conductive pad 32 may be in a range of about 2.2 μm to about 5.5 μm, which is thinner than the thickness of some comparative ball pads formed by etching a copper foil. Portions of the first metal layer 331 and the second metal layer 332 that are disposed on the first surface 21 of the dielectric structure 2 constitute the first conductive traces 34. The conductive pads 32 and the first conductive traces 34 are formed concurrently and integrally as a monolithic structure (the redistribution layer structure 3 has an approximately consistent thickness), but they are not disposed at the same level. The location of the first conductive traces 34 is higher than the location of the conductive pads 32 (e.g., the first conductive traces 34 are disposed on a plane above a plane on which the conductive pads 32 are disposed). Thus, the redistribution layer structure 3 defines a plurality of recess portions 36 corresponding to the conductive pads 32 disposed in the through holes 23 of the dielectric structure 2. In addition, a line width/line space (L/S) of the redistribution layer structure 3 may be in a range of about 2 μm/about 2 μm to about 10 μm/about 10 μm. As shown in FIG. 1, the width W3 of the conductive pad 32 is substantially equal to the width W1 of the first portion of the through hole 23.

The insulation structure 6 is disposed on at least a portion of the first surface 21 of the dielectric structure 2 and the redistribution layer structure 3. The insulation structure 6 may be, for example, a passivation layer or a solder mask layer. In some embodiments, the insulation structure 6 may include, or be formed from, a cured photoimageable dielectric (PID) material such as epoxy or polyimide (PI) including photoinitiators. The insulation structure 6 has a first surface 61 and a second surface 62 opposite to the first surface 61, and defines a plurality of openings 63 that expose portions of the first conductive traces 34 of the redistribution layer structure 3. Further, the first surface 61 of the insulation structure 6 may define a cavity 64 corresponding to the recess portions 36 of the redistribution layer structure 3.

The conductive circuit layer 7 is disposed on at least a portion of, or embedded in, the insulation structure 6, and in the openings 63 defined by the insulation structure 6. The conductive circuit layer 7 includes a plurality of second conductive traces 76 and a plurality of bump pads 74. The second conductive traces 76 may be disposed on at least a portion of the first surface 61 of the insulation structure 6 or embedded in the insulation structure 6, and are electrically connected to the bump pads 74. Each of the bump pads 74 is disposed in a respective opening 63 defined by the insulation structure 6 and on a respective first conductive trace 34, and may protrude from the insulation structure 6. The conductive circuit layer 7 may include a plurality of metal layers. As shown in FIG. 1, the conductive circuit layer 7 includes a third metal layer 71, a fourth metal layer 72 and a fifth metal layer 73. The material of the third metal layer 71 may include, for example, copper, the material of the fourth metal layer 72 may include, for example, nickel, and the material of the fifth metal layer 73 may include, for example, gold. The third metal layer 71, the fourth metal layer 72 and the fifth metal layer 73 are formed by sputtering and plating, and thus, they can be made very thin. In one or more embodiments, the material of the fifth metal layer 73 may include, for example, tin, and the conductive circuit layer 7 may further include a silver layer on the tin layer.

As shown in FIG. 1, the portions of the third metal layer 71, the fourth metal layer 72 and the fifth metal layer 73 that are disposed in the opening 63 defined by the insulation structure 6 and which may protrude from the insulation structure 6 constitute the bump pads 74. The portions of the third metal layer 71, the fourth metal layer 72 and the fifth metal layer 73 that are disposed on the first surface 61 of the insulation structure 6 are patterned and constitute the second conductive traces 76. In addition, a line width/line space (L/S) of the conductive circuit layer 7 may be less than or equal to about 2 μm/about 2 μm.

The semiconductor die 4 is electrically connected to the redistribution layer structure 3. In one or more embodiments, the semiconductor die 4 includes a plurality of metal pillars 42 and a plurality of solder connectors 44. The metal pillars 42 are connected to the bump pads 74 through the solder connectors 44 such that the semiconductor die 4 can be electrically connected to the redistribution layer structure 3. An underfill 14 is disposed in the space between the semiconductor die 4 and the insulation structure 6 such that it covers and protects the bump pads 74, the solder connectors 44 and the metal pillars 42. The encapsulant 12, which may include, for example, a molding compound, covers at least a portion of one side surface of the semiconductor die 4, the underfill 14 and the first surface 61 of the insulation structure 6. The top surface 121 of the encapsulant 12 is substantially coplanar with the top surface 41 of the semiconductor die 4 such that heat from the semiconductor die 4 can be dissipated.

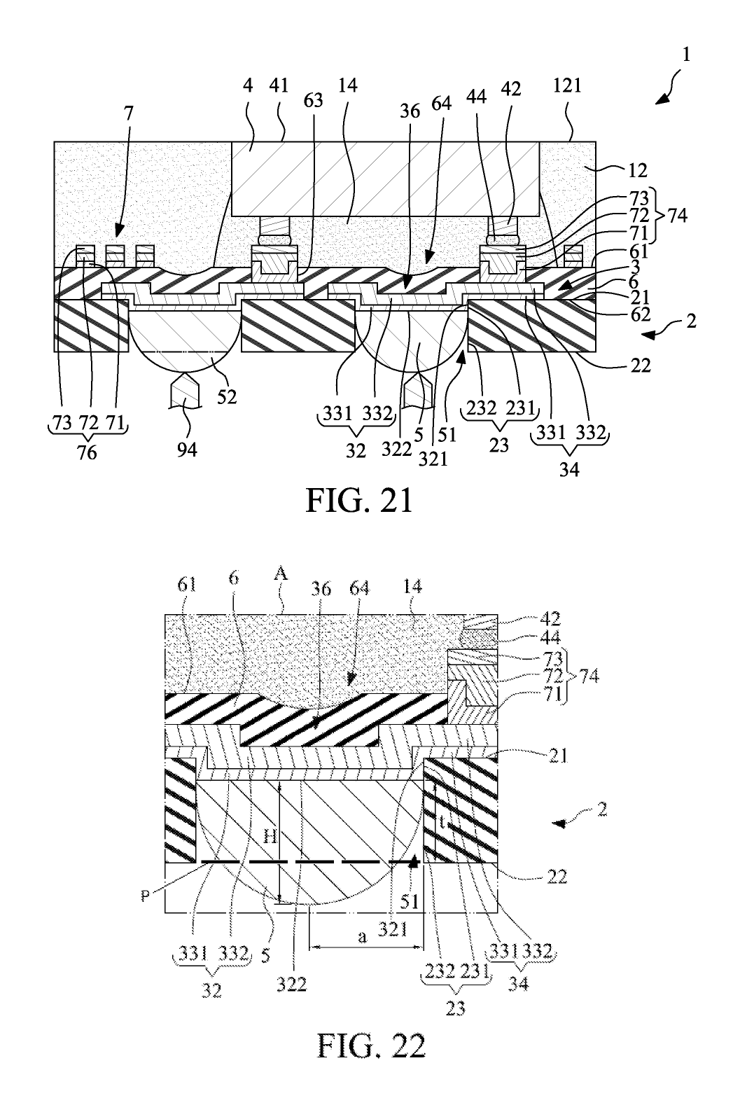

The conductive structures 5, which can be, for example, solder balls, are each disposed on a respective one of the conductive pads 32 and are disposed in the second portion of the through hole 23. A gap or space 51 is defined by a sidewall of the conductive structure 5 and the second sidewall portion 232 of the through hole 23. In some embodiments, a volume of the conductive structure 5 is substantially equal to a volume defined by the bottom surface 322 of the conductive pad 32, the second sidewall portion 232 of the through hole 23, and a plane parallel to the bottom surface 322 and coplanar with the second surface 22 of the dielectric structure 2. Thus, a volume of a portion 52 of the conductive structure 5 that protrudes beyond the second surface 22 of the dielectric structure 2 is substantially equal to the volume of the gap or space 51. In some embodiments, each of the conductive structures 5 has a substantially hemisphere shape. As shown in FIG. 1, two adjacent conductive structures 5 are separated by the dielectric structure 2, and a thickness of the dielectric structure 2 may be greater than one half of a height H (shown in FIG. 22) of the conductive structure 5. Thus, the thick dielectric structure 2 can help to prevent a conductive bridge, such as a solder bridge, from forming between the two adjacent conductive structures 5.

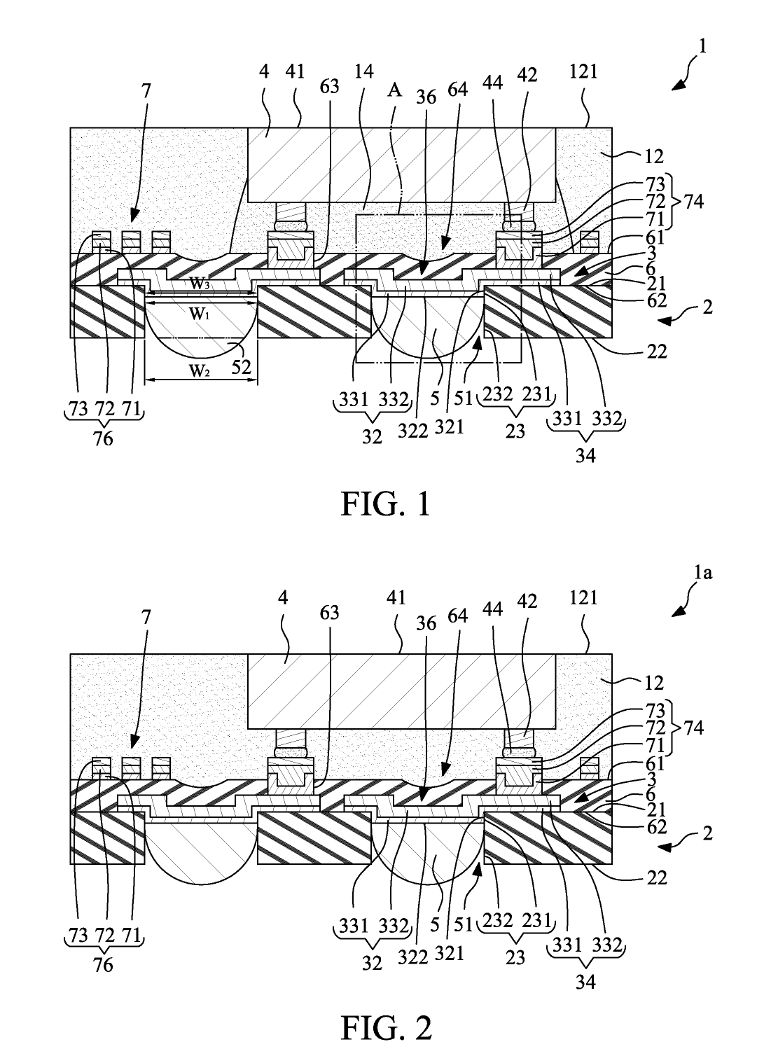

FIG. 2 illustrates a cross-sectional view of a semiconductor package structure 1a according to some embodiments of the present disclosure. The semiconductor package structure 1a is similar in certain respects to the semiconductor package structure 1 as shown in FIG. 1, except that the underfill 14 depicted in FIG. 1 is omitted. Therefore, the encapsulant 12 further extends into a space between the semiconductor die 4 and the insulation structure 6 and covers and protects the bump pads 74, the solder connectors 44 and the metal pillars 42.

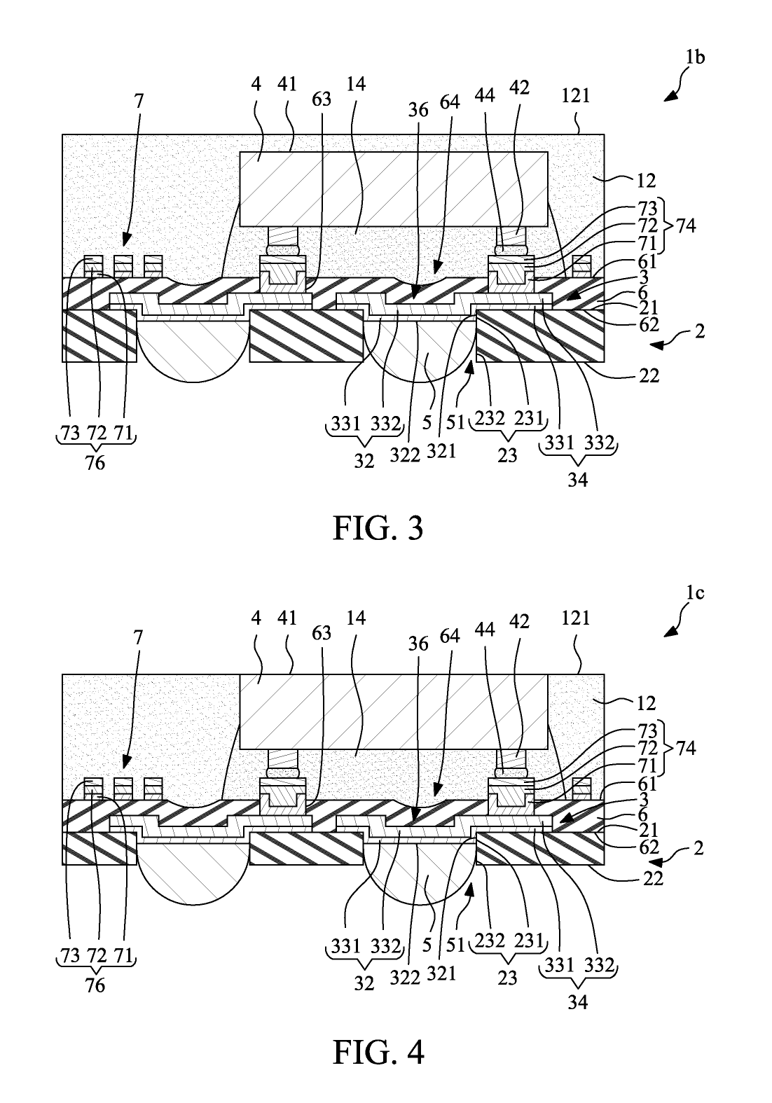

FIG. 3 illustrates a cross-sectional view of a semiconductor package structure 1b according to some embodiments of the present disclosure. The semiconductor package structure 1b is similar in certain respects to the semiconductor package structure 1 as shown in FIG. 1, except that the encapsulant 12 further covers the top surface 41 of the semiconductor die 4. That is, the top surface 121 of the encapsulant 12 is higher than the top surface 41 of the semiconductor die 4.

FIG. 4 illustrates a cross-sectional view of a semiconductor package structure 1c according to some embodiments of the present disclosure. The semiconductor package structure 1c is similar in certain respects to the semiconductor package structure 1 as shown in FIG. 1, except that the dielectric structure 2 has been thinned from its second surface 22 such that the dielectric structure 2 depicted in FIG. 4 is thinner than the dielectric structure 2 depicted in FIG. 1. In other embodiments, the dielectric structure 2 depicted in FIG. 4 can be manufactured to be thinner than the dielectric structure 2 depicted in FIG. 1. Thus, the volume of the gap or space 51 can be reduced. The conductive pads 32 and the conductive structures 5 depicted in FIG. 4 can be used for a land grid array (LGA) connection.

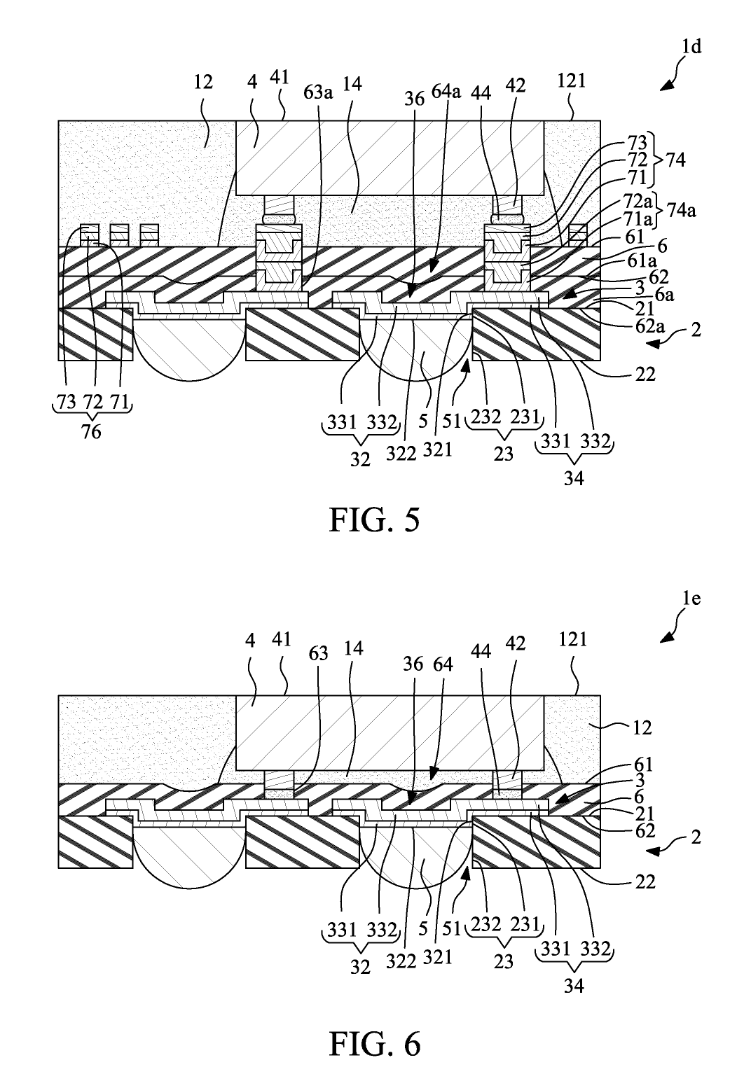

FIG. 5 illustrates a cross-sectional view of a semiconductor package structure 1d according to some embodiments of the present disclosure. The semiconductor package structure 1d is similar in certain respects to the semiconductor package structure 1 as shown in FIG. 1, except that an intermediate insulation structure 6a is sandwiched between the insulation structure 6 and the dielectric structure 2. The intermediate insulation structure 6a is disposed on at least a portion of the first surface 21 of the dielectric structure 2 and at least a portion of the redistribution layer structure 3. The intermediate insulation structure 6a may be, for example, a passivation layer or a solder mask layer. In some embodiments, the intermediate insulation structure 6a may include, or be formed from, a cured photoimageable dielectric (PID) material such as epoxy or polyimide (PI) having photoinitiators. The material of the intermediate insulation structure 6a may be the same or different from the material of the insulation structure 6. The intermediate insulation structure 6a has a first surface 61a and a second surface 62a opposite to the first surface 61a, and defines a plurality of openings 63a that expose portions of the first conductive traces 34 of the redistribution layer structure 3. Further, the first surface 61a of the insulation structure 6a may define a cavity 64a corresponding to the recess portions 36 of the redistribution layer structure 3. Each of the bump pads 74a (including the third metal layer 71a and the fourth metal layer 72a) is disposed in a respective opening 63a defined by the insulation structure 6a and on a respective first conductive trace 34 and may protrude from the insulation structure 6a. The openings 63 defined by the insulation structure 6 are aligned with the openings 63a defined by the insulation structure 6a, such that the bump pads 74 disposed in the openings 63 defined by the insulation structure 6 can contact the bump pads 74a in the openings 63a defined by the insulation structure 6a. In some embodiments, there may be a plurality of second conductive traces (not shown) disposed on the first surface 61a of the intermediate insulation structure 6a.

FIG. 6 illustrates a cross-sectional view of a semiconductor package structure 1e according to some embodiments of the present disclosure. The semiconductor package structure 1e is similar in certain respects to the semiconductor package structure 1 as shown in FIG. 1, except that conductive circuit layer 7 (including the second conductive traces 76 and the bump pads 74) depicted in FIG. 1 is omitted. Therefore, the solder connectors 44 of the semiconductor die 4 directly contact the first conductive traces 34 of the redistribution layer structure 3 disposed in the openings 63 defined by the insulation structure 6.

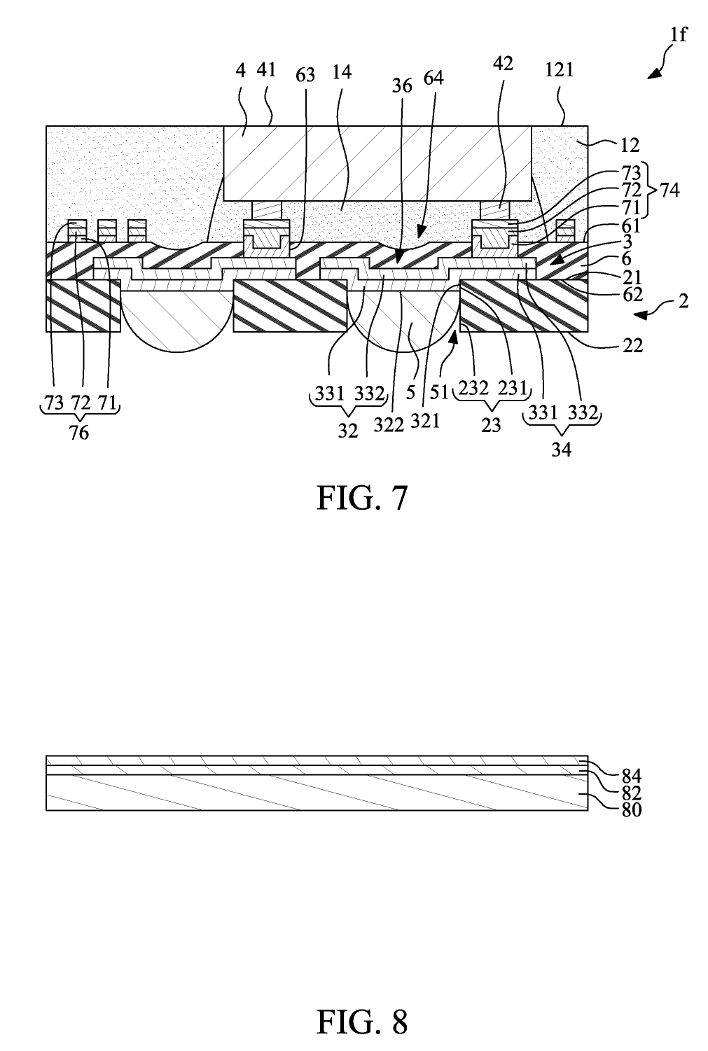

FIG. 7 illustrates a cross-sectional view of a semiconductor package structure if according to some embodiments of the present disclosure. The semiconductor package structure if is similar in certain respects to the semiconductor package structure 1 as shown in FIG. 1, except that the solder connectors 44 depicted in FIG. 1 are omitted. Therefore, the metal pillars 42 of the semiconductor die 4 contact the bump pads 74 of the conductive circuit layer 7 directly. In some embodiments, the metal pillars 42 are connected to the fifth metal layer 73 by metal-to-metal bonding.

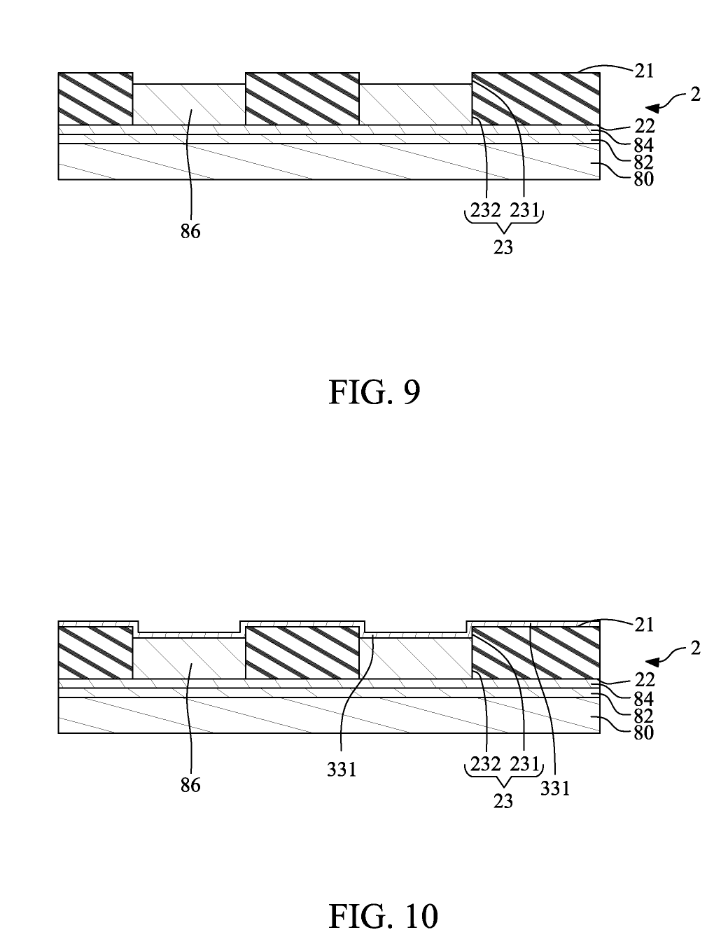

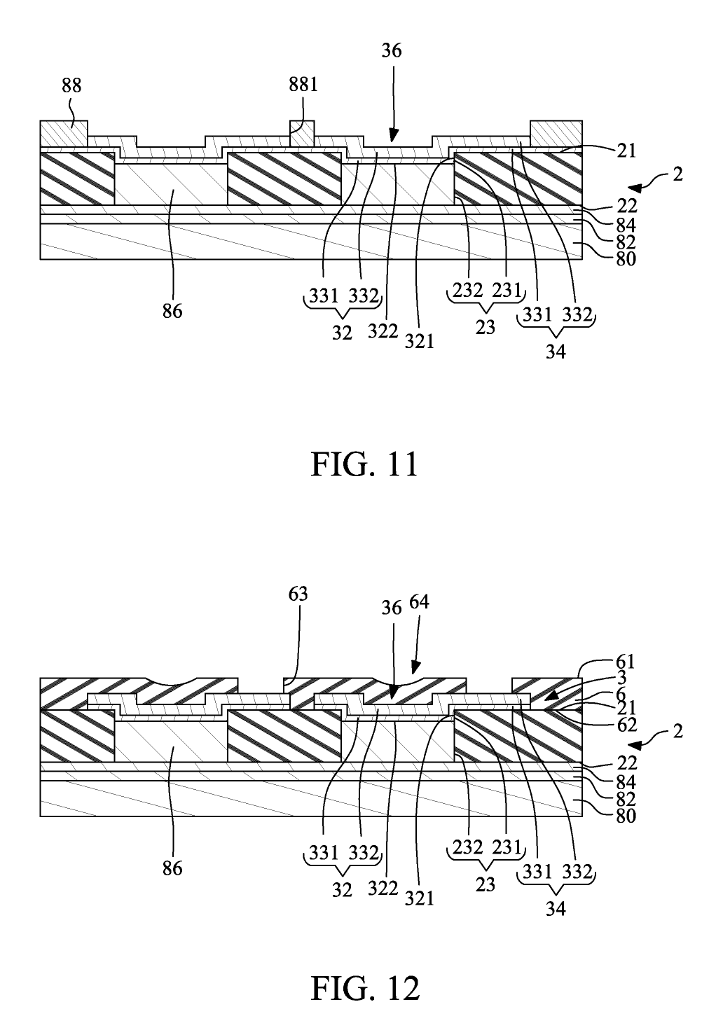

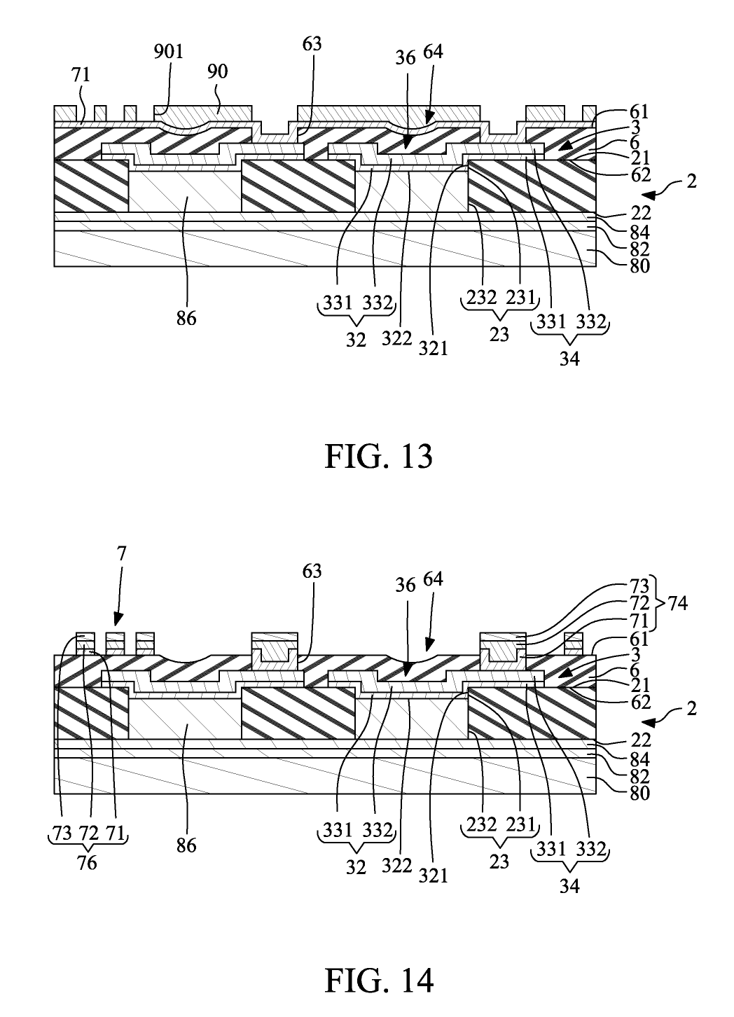

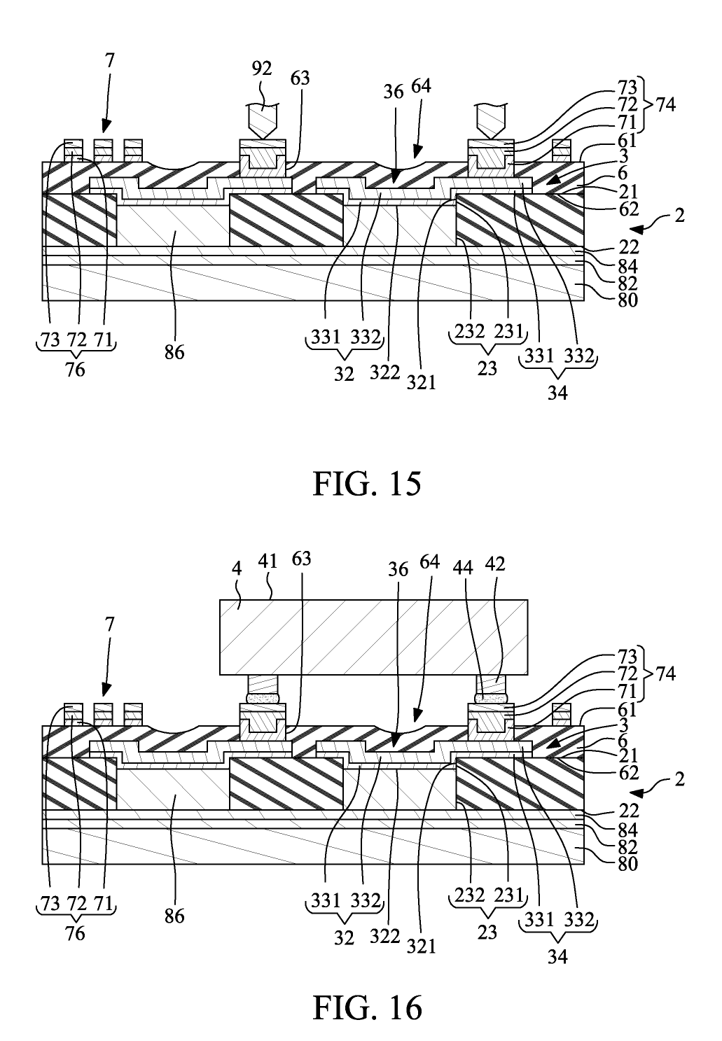

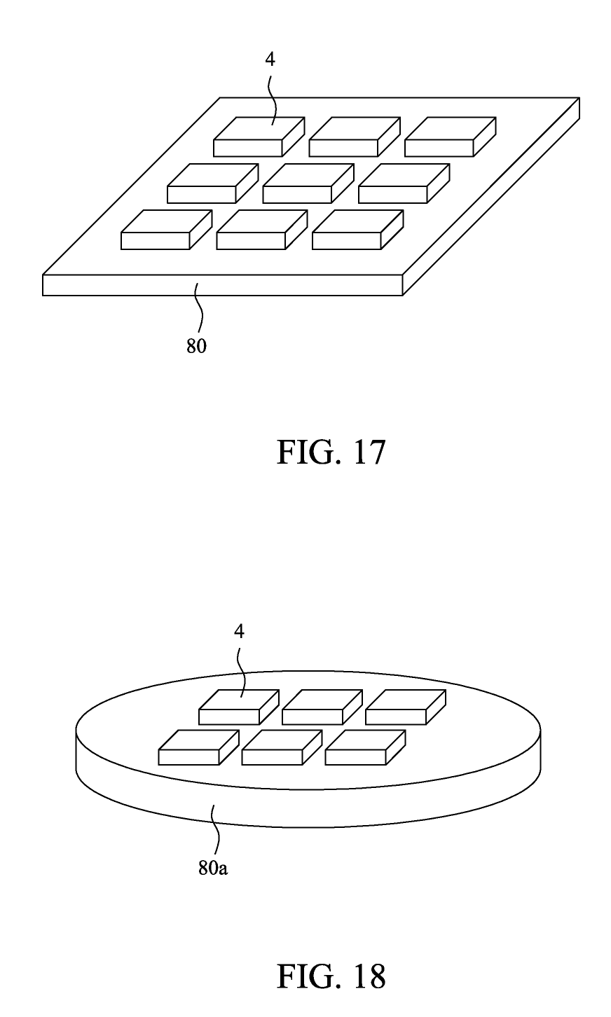

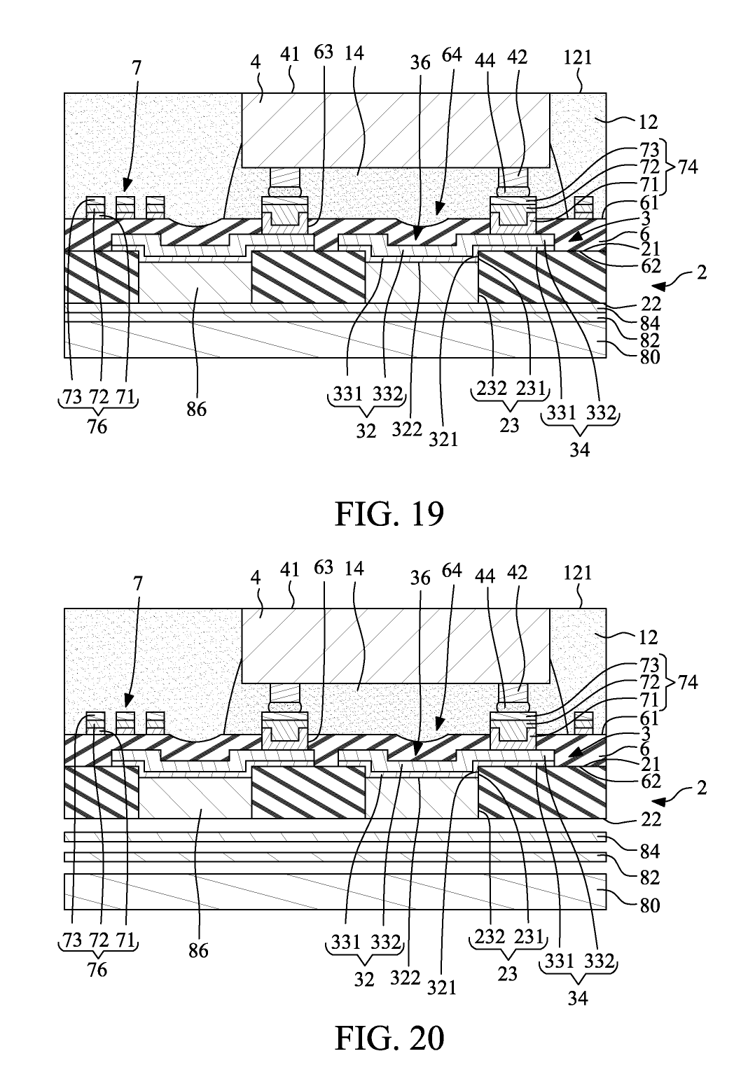

FIGS. 8-21 illustrate a method for manufacturing a semiconductor package structure according to some embodiments of the present disclosure. Referring to FIG. 8, a carrier 80 is provided. In one or more embodiments, the material of the carrier 80 may be organic (e.g., may include polypropylene (PP) resin or bismaleimide triazine (BT) resin) or inorganic (e.g., may include glass, silicon, ceramic or metal). The carrier 80 may be rectangular, square, circular, elliptical or other shape from a top view. A metal layer 84, such as a copper foil, is attached to the carrier 80 via an adhesion layer 82.

Referring to FIG. 9, the dielectric structure 2 is formed on the metal layer 84. The dielectric structure 2 may be, for example, a passivation layer or a solder mask layer. In some embodiments, the dielectric structure 2 may include, or be formed from, a cured photoimageable dielectric (PID) material such as epoxy or polyimide (PI) including photoinitiators. The dielectric structure 2 has a first surface 21 and a second surface 22 opposite to the first surface 21, and defines a plurality of through holes 23. The through holes 23 may be formed by, for example, a lithography technique. Each of the through holes 23 extends through the dielectric structure 2 such that a portion of the metal layer 84 is exposed, and includes a first sidewall portion 231 that defines a first portion of the through hole 23 and a second sidewall portion 232 that defines a first portion of the through hole 23. The second sidewall portion 232 and the first sidewall portion 231 are substantially coplanar with each other and are formed concurrently. In some embodiments, each of the through holes 23 has an approximately consistent diameter. Then, a plurality of conductive material deposits 86 (e.g., solder material) are formed on an exposed portion of the metal layer 84 in the respective ones of the through holes 23 by, for example, plating. It is noted that the conductive material deposit 86 does not fill the through hole 23 completely. As shown in FIG. 9, the conductive material deposit 86 fills a second portion of the through hole 23 defined by the second sidewall portion 232, and a first portion of the through hole 23 defined by the first sidewall portion 231 is left empty at this stage. Thus, a thickness of the conductive material deposit 86 is less than a thickness of the dielectric structure 2.

Referring to FIG. 10, the first metal layer 331 is formed and covers the conductive material deposit 86 and at least a portion of the first surface 21 of the dielectric structure 2 by, for example, sputtering. The material of the first metal layer 331 may include titanium, and a thickness of the first metal layer 331 may be about 0.2 μm. It is noted that the first metal layer 331 is capable of acting as a barrier layer.

Referring to FIG. 11, a photoresist layer 88 is formed on the first metal layer 331. The photoresist layer 88 defines a plurality of openings 881 that expose portions of the first metal layer 331. Then, the second metal layer 332 is formed on the first metal layer 331 in the openings 881 of the photoresist layer 88 by, for example, plating. The material of the second metal layer 332 may include copper, and a thickness of the second metal layer 332 may be in a range of about 2 μm to about 5 μm. The first metal layer 331 and the second metal layer 332 are formed by sputtering and plating, respectively, and thus, they can be very thin.

Then, the photoresist layer 88 is removed by, for example, stripping. Then, the portions of the first metal layer 331 that are not covered by the second metal layer 332 are removed by, for example, etching so as to form the redistribution layer structure 3. The redistribution layer structure 3 includes the conductive pads 32 and the first conductive traces 34. Each of the conductive pads 32 is disposed in a respective through hole 23, and a sidewall 321 of the conductive pad 321 contacts the first sidewall portion 231 of the through hole 23. That is, portions of the first metal layer 331 and the second metal layer 332 that are disposed in the first portion of the through hole 23 constitute the conductive pad 32. The conductive pad 32 is sometimes be referred to herein as a “ball pad”. The thickness of the conductive pad 32 may be in a range of about 2.2 μm to about 5.5 μm, which is thinner than the thickness of some comparative ball pads formed by etching a copper foil. Portions of the first metal layer 331 and the second metal layer 332 that are disposed on the first surface 21 of the dielectric structure 2 constitute the first conductive traces 34. The conductive pads 32 and the first conductive traces 34 are formed concurrently, but they are not at the same level. The first conductive traces 34 are disposed higher than the conductive pads 32. Thus, the redistribution layer structure 3 defines a plurality of recess portions 36 corresponding to the conductive pads 32 disposed in the through holes 23 of the dielectric structure 2. In addition, a line width/line space (L/S) of the redistribution layer structure 3 may be in a range of about 2 μm/about 2 μm to about 10 μm/about 10 μm. It is noted that even if the metal layer 84 is a copper foil, should wrinkling occur, the precision of the size of the redistribution layer structure 3 will not be affected.

Referring to FIG. 12, the insulation structure 6 is formed on at least a portion of the dielectric structure 2 and at least a portion of the redistribution layer structure 3. The insulation structure 6 may be, for example, a passivation layer or a solder mask layer. In some embodiments, the insulation structure 6 may include, or be formed from, a cured photoimageable dielectric (PID) material such as epoxy or polyimide (PI) with photoinitiators. The insulation structure 6 has a first surface 61 and a second surface 62 opposite to the first surface 61, and defines a plurality of openings 63 that expose portions of the first conductive traces 34 of the redistribution layer structure 3. Further, the first surface 61 of the insulation structure 6 may define a cavity 64 corresponding to the recess portions 36 of the redistribution layer structure 3.

Referring to FIG. 13, a third metal layer 71 is formed on the insulation structure 6 and in the openings 63 by, for example, sputtering. Then, a photoresist layer 90 is formed on the third metal layer 71. The photoresist layer 90 defines a plurality of openings 901 that expose portions of the third metal layer 71.

Referring to FIG. 14, a fourth metal layer 72 and a fifth metal layer 73 are formed on the third metal layer 71 in the openings 901 of the photoresist layer 90 by, for example, plating. Then, the photoresist layer 90 is removed by, for example, stripping. Then, the portions of the third metal layer 71 that are not covered by the fourth metal layer 72 and the fifth metal layer 73 are removed by, for example, etching, thus forming a conductive circuit layer 7. The conductive circuit layer 7 includes a plurality of second conductive traces 76 and a plurality of bump pads 74. The second conductive traces 76 may be disposed on the first surface 61 of the insulation structure 6, and are electrically connected to the bump pads 74. Each of the bump pads 74 is disposed in a respective opening 63 of the insulation structure 6 and on a respective first conductive trace 34. In addition, a line width/line space (L/S) of the conductive circuit layer 7 may be less than or equal to about 2 μm/about 2 μm.

Referring to FIG. 15, an electrical test is conducted to the bump pads 74 by probes 92. In the depicted embodiments, the electrical test can be performed before a die mounting process is performed. Therefore, a failure of the conductive circuit layer 7 and/or the redistribution layer structure 3 can be found immediately, which can raise the yield rate and lower the manufacturing cost.

Referring to FIG. 16, the semiconductor die 4 is electrically connected to the redistribution layer structure 3 by flip chip bonding techniques. In one or more embodiments, the semiconductor die 4 includes a plurality of metal pillars 42 and a plurality of solder connectors 44. The metal pillars 42 are connected to the bump pads 74 through the solder connectors 44 such that the semiconductor die 4 can be electrically connected to the redistribution layer structure 3.

FIG. 17 illustrates a schematic perspective view of the carrier 80 and the semiconductor dice 4 depicted in FIG. 16 according to some embodiments of the present disclosure. The carrier 80 may be rectangular or square.

FIG. 18 illustrates a schematic perspective view of the carrier 80a and the semiconductor dice 4 depicted in FIG. 16 according to some embodiments of the present disclosure. The carrier 80a may be circular or elliptical.

Referring to FIG. 19, an underfill 14 is applied to a space between the semiconductor die 4 and the insulation structure 6 and covers and protects the bump pads 74, the solder connectors 44 and the metal pillars 42. Then, the encapsulant 12, such as including a molding compound, is formed and covers at least a portion of a side surface of the semiconductor die 4, the underfill 14 and the first surface 61 of the insulation structure 6. In one or more embodiments, the top surface 121 of the encapsulant 12 is substantially coplanar with the top surface 41 of the semiconductor die 4 such that heat from the semiconductor die 4 can be dissipated.

Referring to FIG. 20, the carrier 80, the adhesion layer 82 and the metal layer 84 are removed from the dielectric structure 2 and the conductive material deposits 86 are exposed. In one or more embodiments, a plurality of semiconductor dice 4 are disposed on the dielectric structure 2 and form a panel structure. In this stage, the carrier 80 is removed from the panel structure, and a slight warpage may occur on the panel structure. For example, the size of the panel structure may be about 300 mm×about 300 mm, and a thickness of the panel structure may be less than about 0.3 mm. After the de-carrier stage depicted in FIG. 20, the warpage of the panel structure may be less than about 35 mm.

Referring to FIG. 21, a reflow process is conducted to heat and melt the conductive material deposits 86 to form a plurality of conductive structures 5. Each of the conductive structures 5 may form in a substantially hemisphere shape due to, for example, a cohesion force, and a portion 52 of the conductive structure 5 may protrude beyond the second surface 22 of the dielectric structure 2. Since the conductive structures 5 are formed by melting the conductive material deposits 86 that are attached to the conductive pads 32 (ball pads) in the previous stage rather than by a ball mounting process, even if warpage of the dielectric structure 2 of the panel structure occurs, the conductive structures 5 still can be formed at precise locations. In one or more embodiments as described above, the panel structure may have a warpage of less than about 35 mm. However, such warpage will not significantly affect the precision of the formation of the conductive structures 5. Further, most-protruded portions of the conductive structures 5 on the panel structure may be, for example, within less than about a 50 μm difference in vertical disposition.

Then, a singulation is performed to form a plurality of semiconductor package structures 1 as shown in FIG. 1. Then, an electrical test can be conducted to the conductive structures 5 by the probes 94.

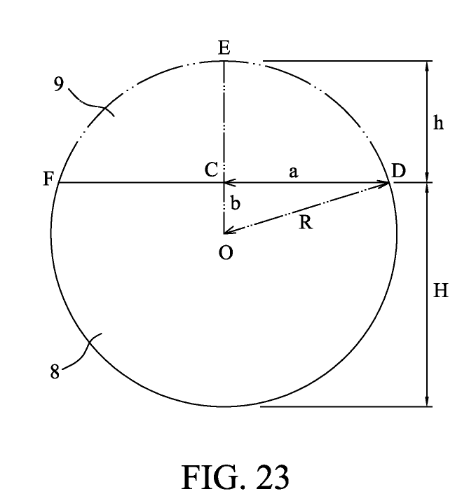

FIG. 22 illustrates an enlarged view of an area “A” depicted in FIG. 1 according to the embodiments depicted in FIG. 1. FIG. 23 illustrates a schematic view of a depiction of a cross section of the conductive structure 5. The first part 8 shown in FIG. 23 is a depiction of the conductive structure 5 depicted in FIG. 22, and the line segment FD shown in FIG. 23 is a depiction of the bottom surface 322 of the conductive pad 32 depicted in FIG. 22. The second part 9 shown in FIG. 23 is imaginary. The first part 8 and the second part 9 depicted in FIG. 23 form a sphere (shown in cross section as a circle in FIG. 23) having a center point “O”, a radius “R” and a top point “E”. As depicted in FIG. 22, a depth of the second portion of the through hole 23 defined by the second sidewall portion 232 is defined as “t”, a height of the conductive structure 5 is defined as “H”, and a width W3 of the conductive pad 32 is equal to twice the length “a”.

As shown in FIG. 23, line segment OE intersects line segment FD at the point “C”. The length of the line segment CE is equal to “h”, the length of the line segment CD is equal to “a”, the length of the line segment OC is equal to “b” and the length of the line segment OD is equal to “R”. The following geometric analysis describes relationships between some of the lengths, heights, widths and dispositions of various elements and components depicted in FIG. 22.

h+H=2R, thus, h=2R−H (1)

In addition, b=R−h. In the triangle OCD, b²=R²−a² (2)

Thus, (R−h)²=R²−a² (3)

R−h=\sqrt{R²−a²} (4)

h=R−\sqrt{R²−a²} (5)

Equating the right hand side of Equation (1) to the right hand side of equation (5),

2R−H=R−\sqrt{R²−a²} (6)

H−R=\sqrt{R²−a²} (7)

H²−2HR+R²=R²−a² (8)

Therefore, 2HR=H²+a² (9)

R=H/2+a²/2H (10)

According to geometric principles, the total volume Vₜ of the sphere depicted in FIG. 23 can be expressed as:

Vₜ=4πR³/3 (11)

Also, the volume Vₙ of the second part 9 can be expressed as:

Vₙ=πh²(R−h/3) (12)

The volume ΔV of the first part 8 can be expressed as:

ΔV=Vₜ−Vₙ=4πR³/3−πh²(R−h/3) (13)

Meanwhile, the volume of the conductive structure 5 is equal to the volume Vₚ of the conductive material deposits 86 formed by plating and can be expressed as:

Vₚ=πa²t (14)

According to the law of conservation of volume, the volume Vₚ of the conductive material deposits 86 is equal to volume ΔV of the first part 8. That is, the right hand side of equation (13) is equal to the right hand side of equation (14), so that

πa²t=4πR³/3−πh²(R−h/3) (15)

Thus, t=[4R³/3−h²(R−h/3)]/a² (16)

Substituting R of equation (10) into equation (16) results in equation (17).

t=[4(H/2+a²/2H)³/3−h²(H/2+a²/2H−h/3)]/a² (17)

Under a design rule that allows for a range of variation of ±5% for t, equation (17) becomes as shown in equation (18).

t=[4(H/2+a²/2H)³/3−h²(H/2+a²/2H−h/3)]/a²±5% (18)

Therefore, the thickness t of the conductive material deposits 86 at the stage depicted in FIG. 9 can be determined by equation (18). By selecting a thickness t for the conductive material deposits 86 in accordance with equation (18), appropriately sized conductive structures 5 can be formed in accordance with the methods described herein. In comparison, some comparative panel structures may have a size of about 300 mm×about 300 mm, and a thickness of less than 300 μm. After the de-carrier stage, the maximum warpage of the panel structure may be about 35 mm. Thus, it can be very difficult to mount solder balls on those comparative panel structures. In addition, the methods described herein allow the conductive structure 5 to be formed by heating the pre-plated conductive material deposit 86, and thus, the diameter of the conductive structure 5 can be made smaller than the diameter of some comparative solder balls. For example, the diameter of the conductive structure 5 may be less than about 70 μm, whereas the diameter of some comparative solder balls can be greater than about 70 μm.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor package structure, comprising:
a dielectric structure defining a through hole, wherein the through hole includes a first portion defined by a first sidewall portion and a second portion defined by a second sidewall portion substantially coplanar with the first sidewall portion;
a redistribution layer structure disposed on a first surface of the dielectric structure, including a conductive pad and a first conductive trace, wherein the conductive pad is disposed in the through hole, and a sidewall of the conductive pad contacts the first sidewall portion of the through hole;
a semiconductor die electrically connected to the redistribution layer structure; and
a conductive structure disposed on the conductive pad and disposed in the second portion of the through hole;
wherein a sidewall of the conductive structure and the second sidewall portion of the through hole define a gap.

2. The semiconductor package structure according to claim 1, further comprising:
an insulation structure disposed on at least a portion of the dielectric structure and at least a portion of the redistribution layer structure, which defines an opening that exposes the first conductive trace of the redistribution layer structure; and
a bump pad disposed in the opening of the insulation structure and on the first conductive trace.

3. The semiconductor package structure according to claim 2, further comprising a second conductive trace disposed on or embedded in the insulation structure, wherein the second conductive trace is electrically connected to the bump pad.

4. The semiconductor package structure according to claim 1, wherein the through hole has a consistent diameter.

5. The semiconductor package structure according to claim 1, wherein the redistribution layer structure includes a plurality of metal layers.

6. The semiconductor package structure according to claim 1, wherein the redistribution layer structure defines a recess portion corresponding to the through hole of the dielectric structure.

7. The semiconductor package structure according to claim 1, wherein the first conductive trace is disposed on a plane above a plane on which the conductive pad is disposed.

8. The semiconductor package structure according to claim 1, wherein a volume of a portion of the conductive structure that protrudes beyond a second surface of the dielectric structure opposite the first surface is substantially equal to a volume of the gap.

9. The semiconductor package structure according to claim 1, wherein a width of the conductive pad is substantially equal to a width of the first portion of the through hole.

10. The semiconductor package structure according to claim 1, wherein a depth of the second sidewall portion of the through hole of the dielectric structure is specified as t, a height of the conductive structure is specified as H, a width of the conductive pad is specified as 2a, wherein the conductive structure is approximately in a shape of a portion of a sphere of radius R, wherein the relationship h=2R−H is satisfied, and wherein
t=[4(H/2+a²/2H)³/3−h²(H/2+a²/2H−h/3)]/a²±5%

11. A semiconductor package structure, comprising:
a dielectric structure having a top surface and defining a plurality of through holes;
a redistribution layer structure disposed on at least a portion of the top surface of the dielectric structure, including a plurality of conductive pads and a plurality of first conductive traces, wherein each of the conductive pads is disposed in a respective through hole, and a sidewall of each of the conductive pads contacts a sidewall of the respective through hole;
a semiconductor die electrically connected to the redistribution layer structure; and
a plurality of conductive structures each disposed on a respective one of the conductive pads and in a respective one of the through holes, wherein a portion of each of the conductive structures protrudes beyond a bottom surface of the dielectric structure, and wherein a volume of the entire conductive structure is substantially equal to a volume defined by a bottom surface of the conductive pad, the sidewall of the through hole, and a plane parallel to the bottom surface of the conductive pad and coplanar with the bottom surface of the dielectric structure,
and wherein, for each of the conductive pads, a width of the conductive pad disposed in the respective through hole, a width of the respective through hole, and a width of a portion of the conductive pad in contact with the respective conductive structure are substantially equal.

12. The semiconductor package structure according to claim 11, wherein the redistribution layer structure has a consistent thickness.

13. The semiconductor package structure according to claim 11, wherein each of the first conductive traces includes a plurality of metal layers.

14. The semiconductor package structure according to claim 11, wherein the conductive pads and the first conductive traces are formed integrally.

15. The semiconductor package structure according to claim 11, wherein each of the conductive structures is in a substantially hemisphere shape.

16.-20. (canceled)

21. A semiconductor package structure, comprising:
a dielectric structure having a first surface and defining a through hole, wherein a sidewall of the through hole includes a first sidewall portion and a second sidewall portion, the through hole includes a first portion defined by the first sidewall portion and a second portion defined by the second sidewall portion, and the sidewall of the through hole is continuous, and the dielectric structure is a monolithic structure;
a redistribution layer structure disposed on the first surface of the dielectric structure and in the through hole having a first surface facing away from the through hole and a second surface facing the through hole;
a conductive structure disposed on the redistribution layer structure and disposed in the second portion of the through hole; and
a semiconductor die electrically connected to the redistribution layer structure,
wherein a portion of the redistribution layer structure is in contact with the first sidewall portion of the through hole, and a portion of the redistribution layer structure disposed above or in the through hole is recessed towards the through hole.

22. The semiconductor package structure according to claim 21, wherein a thickness of the redistribution layer structure is approximately constant.

23. The semiconductor package structure according to claim 21, wherein the redistribution layer structure includes a conductive pad and a conductive trace, and the recessed portion of the redistribution layer structure is a portion of the conductive pad.

24. The semiconductor package structure according to claim 21, wherein the redistribution layer structure includes a conductive pad and a conductive trace, and wherein the thickness of the conductive pad is in a range of approximately 2.2 micrometers (μm) to approximately 5.5 μm.

25. The semiconductor package structure according to claim 21, further comprising an insulation structure disposed on the redistribution layer structure and over the through hole, wherein a portion of the insulation structure disposed over the through hole is recessed towards the through hole.
